(19) United States
(12) Patent Application Publication
(10) Pub. No.: US 2024/0164090 A1
(43) Pub. Date: May 16, 2024

(54) SEMICONDUCTOR DEVICE AND FABRICATION METHOD THEREOF, AND MEMORY SYSTEM

(71) Applicant: Yangtze Memory Technologies Co., Ltd., Wuhan (CN)

(72) Inventors: Mingkang ZHANG, Wuhan (CN); Liang XIAO, Wuhan (CN); Huan WANG, Wuhan (CN); Shu WU, Wuhan (CN)

(73) Assignee: Yangtze Memory Technologies Co., Ltd., Wuhan (CN)

(21) Appl. No.: 18/090,452

(22) Filed: Dec. 28, 2022

(30) Foreign Application Priority Data
Nov. 16, 2022 (CN) 202211461085.4

(51) Int. Cl. H10B 41/27; H01L 23/528; H10B 41/30; H10B 43/27; H10B 43/30

(52) U.S. Cl. CPC H10B 41/27; H01L 23/5283; H10B 41/30; H10B 43/27; H10B 43/30

(57) ABSTRACT

Aspect of the disclosure provide a semiconductor device including a stack structure having a core region in which a plurality of channel structures are formed, and a semiconductor layer located on one side of the stack structure in a stacking direction of the stack structure, the channel structures extending to the semiconductor layer, and projections of the semiconductor layer and the channel structures in a plane parallel to the stacking direction not overlapping. The semiconductor device can further include a first insulating layer at least located on a first surface of the semiconductor layer far away from the stack structure, and a first leading-out portion penetrating through a portion of the first insulating layer corresponding to the core region in the stacking direction and being in contact with the semiconductor layer.

### INCORPORATION BY REFERENCE

This present application claims the benefit of Chinese Patent Application No. 202211461085.4, filed on Nov. 16, 2022, which is incorporated herein by reference in its entirety.

### BACKGROUND

### Technical Field

Implementations of the present application relate to the technical field of semiconductors, in particular to a semiconductor device and a fabrication method thereof, and a memory system.

### Description of the Related Art

As a feature size of a semiconductor manufacturing process is increasingly smaller, a memory density of a memory device is increasingly higher, and a three-dimensional memory emerges as the times require. To improve a memory capacity of the three-dimensional memory, a number of stack layers of a stack structure and a number of initial channel structures of the three-dimensional memory are increasing. However, with the increase of the number of the stack layers, depths of channel holes also increase, making it difficult to ensure that extending depths of various channel holes are the same during etching of the channel holes, which in turn results in different heights of the initial channel structures formed in subsequent processes, so that formation locations of leading-out components for subsequently connecting the channel structures are limited, thereby increasing the difficulty of a lead process.

### SUMMARY

A semiconductor device and a fabrication method thereof, and a memory system provided by implementations of the present disclosure may solve or partially solve the above defects or other defects in the related art.

A semiconductor device provided according to a first aspect of the present disclosure can include a stack structure including a core region in which a plurality of channel structures are formed, and semiconductor layer located on one side of the stack structure in a stacking direction of the stack structure, the channel structures extending to the semiconductor layer, and projections of the semiconductor layer and the channel structures in a plane parallel to the stacking direction not overlapping. The semiconductor device can further include a first insulating layer at least located on a first surface of the semiconductor layer far away from the stack structure, and a first leading-out portion penetrating through a portion of the first insulating layer corresponding to the core region in the stacking direction and being in contact with the semiconductor layer.

A fabrication method of a semiconductor device provided according to a second aspect of the present disclosure includes forming a first insulating layer on one side of an intermediate semiconductor device, wherein the intermediate semiconductor device comprises a stack structure and a semiconductor layer on one side of the stack structure in a stacking direction of the stack structure, the stack structure comprises a core region in which a plurality of channel structures are formed, the channel structures extend to the semiconductor layer, and projections of the semiconductor layer and the channel structures in a plane parallel to the stacking direction do not overlap, the first insulating layer is at least formed on a first surface of the semiconductor layer far away from the stack structure, and forming a first leading-out portion that penetrates through the first insulating layer in the stacking direction and is in contact with the semiconductor layer in a portion of the first insulating layer corresponding to the core region.

A memory system provided according to a third aspect of the present disclosure includes a controller and the semiconductor device of the first aspect of the present disclosure, the controller is coupled to the semiconductor device and used for controlling the semiconductor device to store data.

By using the intermediate semiconductor device with the projections of the semiconductor layer and the channel structures in the plane parallel to the stacking direction not overlapping, and at least forming the first insulating layer on the first surface of the semiconductor layer far away from the stack structure and forming the first leading-out portion in contact with the semiconductor layer in the portion of the first insulating layer corresponding to the core region, the fabrication method of the semiconductor device provided by the implementations of the present disclosure can not only remove the restriction for a formation location of the first leading-out portion due to different depths of individual channel structures to enable the first leading-out portion to be formed in any location of the first insulating layer corresponding to the core region, without being limited to locations corresponding to gate line slit structures anymore, thereby reducing process difficulty, increasing an overlapping window, but also can significantly reduce difficulty of a subsequent CMP process, decrease an aspect ratio of the first leading-out portion at the same time, expand a scope of selectable materials of the first leading-out portion, make formation of the first leading-out portion directly using aluminum possible, and further omit a tungsten filling process, thereby reducing complexity and cost of a lead process.

The projections of the semiconductor layer and the channel structures of the semiconductor device provided by the implementations of the present disclosure in the plane parallel to the stacking direction do not overlap, in other words, the side of individual channel structures facing towards the semiconductor layer substantially keeps flush, portions of the semiconductor layer formed on the channel structures are also substantially flush, thus the present application can not only enable the first insulating layer to have a thinner thickness, further enable the first leading-out portion to have a smaller aspect ratio, expand a material scope of the first leading-out portion, and make the formation of the first leading-out portion directly using the aluminum possible, thereby omitting a step of forming a first connection portion, reducing the complexity of the lead process, but also can remove the restriction for the formation location of the first leading-out portion due to the different depths of individual channel structures to enable the first leading-out portion to be formed in any location of the first insulating layer corresponding to the core region, without being limited to the locations corresponding to gate line slit structures anymore, thereby reducing the process difficulty of fabricating the first leading-out portion, increasing the overlapping window.

It should be understood that the contents as described in this part is neither intended to identify critical or important features of implementations of the present disclosure, nor used to limit the scope of the present disclosure. Other features of the present disclosure will become easy to understand through the following description.

### BRIEF DESCRIPTION OF THE DRAWINGS

Various implementations of this disclosure that are proposed as examples will be described in detail with reference to the following figures, wherein like numerals reference like elements, and wherein:

FIGS. 1 to 11 are process schematic diagrams of a fabrication method of a semiconductor device according to one implementation of the present disclosure, respectively;

FIG. 12 is a flow chart of a fabrication method of a semiconductor device according to one implementation of the present disclosure;

FIGS. 13 to 21 are partial process schematic diagrams of a fabrication method of a semiconductor device according to another implementation of the present disclosure, respectively;

FIG. 22 is a structural schematic diagram of a semiconductor device according to yet another implementation of the present disclosure;

FIG. 23 is a flow chart of a fabrication method of a semiconductor device according to another implementation of the present disclosure; and

FIG. 24 is a flow chart of a fabrication method of a semiconductor device according to yet another implementation of the present disclosure.

### DETAILED DESCRIPTION

In order for better understanding of the present disclosure, various aspects of the present disclosure will be described in more detail by reference to the accompanying drawings. It is understood that, these detailed descriptions merely describe implementations of the present disclosure, instead of restricting the scope of the present disclosure in any manner. Like reference numbers denote like elements throughout the disclosure. The expression “and/or” includes any or all combinations of one or more of listed associated items.

It is noted that, in this disclosure, the expressions, such as first, second, third and the like, are only used to distinguish one feature from another feature, instead of representing any limitation on the features, particularly instead of representing any sequential order.

For ease of description, the thicknesses, dimensions and shapes of components have been slightly adjusted in the accompanying drawings. The accompanying drawings are merely and are not drawn to scale strictly. As used herein, terms, “approximately”, “about”, and similar terms, are used to represent approximation, instead of representing a degree, and are intended to describe an inherent deviation in a measured value or a calculated value as recognized by those of ordinary skill in the art.

It is also understood that, expressions, such as “comprise”, “comprising”, “have”, “include”, and/or “including”, etc., are open-ended expressions, rather than close-ended expressions in the description. They represent the existence of the stated features, elements and/or components, but do not exclude the existence of one or more other features, elements, components and/or combinations thereof. Moreover, when the expression, such as “at least one of . . . ”, appears after a list of listed features, it modifies the whole list of features, rather than just an individual element in the list. Furthermore, “may” is used to represent “one or more implementation of the present application” when implementations of the present disclosure are described. Moreover, the term “exemplary” is intended to refer to an example or exemplification.

Unless otherwise defined, all phraseologies (including engineering terms and technical terms) as used herein have the same meanings as those generally understood by those of ordinary skill in the art to which the present disclosure pertains. It is further understood that, terms defined in common dictionaries should be interpreted as having a meaning that is consistent with their meaning in the context of the relevant art, and should not be interpreted in an idealized or overly formal sense unless otherwise stated expressly in the present disclosure.

It should be noted that, implementations and features in the implementations in the present disclosure may be combined with one another without conflict. In addition, unless otherwise defined expressly or conflicting with the context, specific steps included in a method as set forth in the present application are not necessarily limited to an order as set forth, but may be carried out in any order or in parallel. The present disclosure will be described in detail below by reference to the accompanying drawings and in conjunction with the implementations.

Furthermore, in the present disclosure, the term “layer” refers to a material portion including a region with a thickness. A layer may extend over the entirety of an underlying or overlying structure, or may have an extent less than the extent of an underlying or overlying structure. Furthermore, a layer may be a region of a homogeneous or inhomogeneous continuous structure that has a thickness less than the thickness of the continuous structure. A layer may extend horizontally, vertically, and/or along an inclined surface. A layer may include multiple sub-layers. In addition, “connection” or “joining”, when used in the present application, may represent direct contact or indirect contact between respective components, unless otherwise expressly defined or derived from the context.

To improve a memory capacity of a three-dimensional memory, a number of stack layers of a stack structure of the three-dimensional memory are increasing. With the increase of the number of the stack layers, depths of channel holes also increase, making it difficult to ensure that extending depths of the various channel holes are the same during etching of the channel holes, which in turn results in different heights of various initial channel structures in an initial semiconductor device.

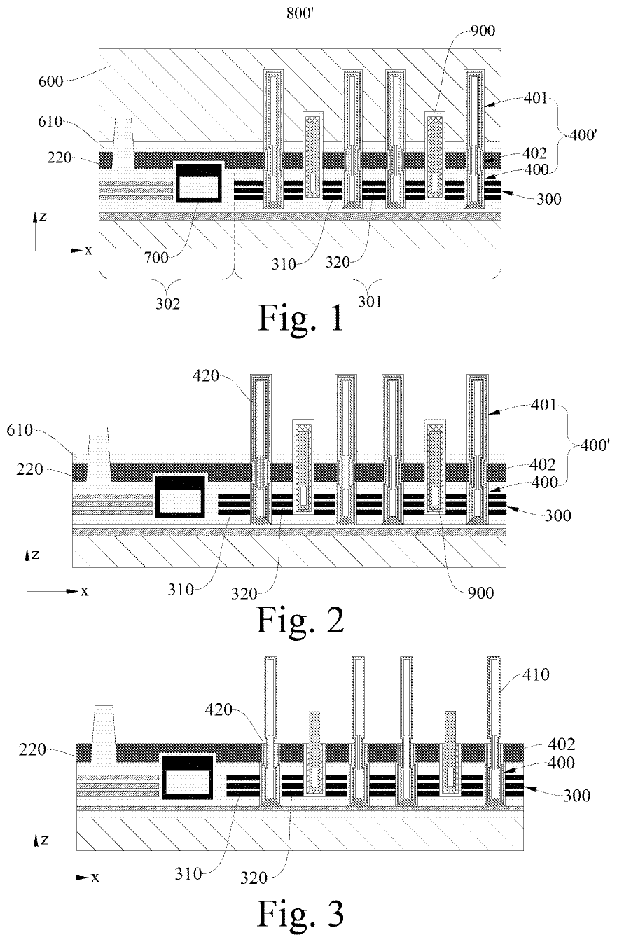

In particular, as shown in FIG. 1, an initial semiconductor device 800′ generally includes a stack structure 300, as well as a non-doped semiconductor layer 220, a substrate insulating layer 610 and a substrate 600 that are disposed in sequence in a stacking direction of the stack structure 300; the stack structure 300 includes a core region 301 in which a plurality of initial channel structures 400′ are formed, and a periphery region 302 located on one side of the core region 301, the stack structure 300 includes gate layers 310 and second insulating layers 320 alternately stacked in the stacking direction within the core region 301, a word line connection portion 700 electrically connected with the gate layers 310 is formed within the periphery region 302, the initial channel structures 400′ penetrate through the stack structure 300, the non-doped semiconductor layer 220 and the substrate insulating layer 610 in sequence and extend into the substrate 600.

Based on the above initial semiconductor device 800′, one implementation of the present disclosure provides a fabrication method of a semiconductor device. For ease of description, as shown in FIG. 1, portions of the initial channel structures 400′ in the substrate 600 and the substrate insulating layer 610 may be referred to as sacrificial structures 401, portions of the initial channel structures 400′ in the non-doped semiconductor layer 220 may be referred as narrowed structures 402, and portions of the initial channel structures 400′ in the stack structure 300 may be referred as channel structures 400.

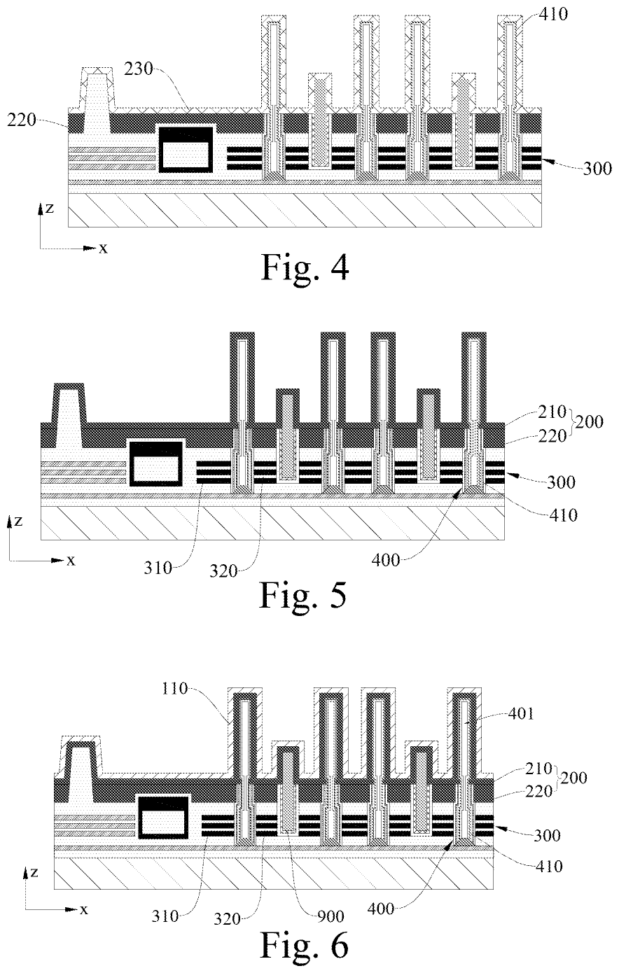

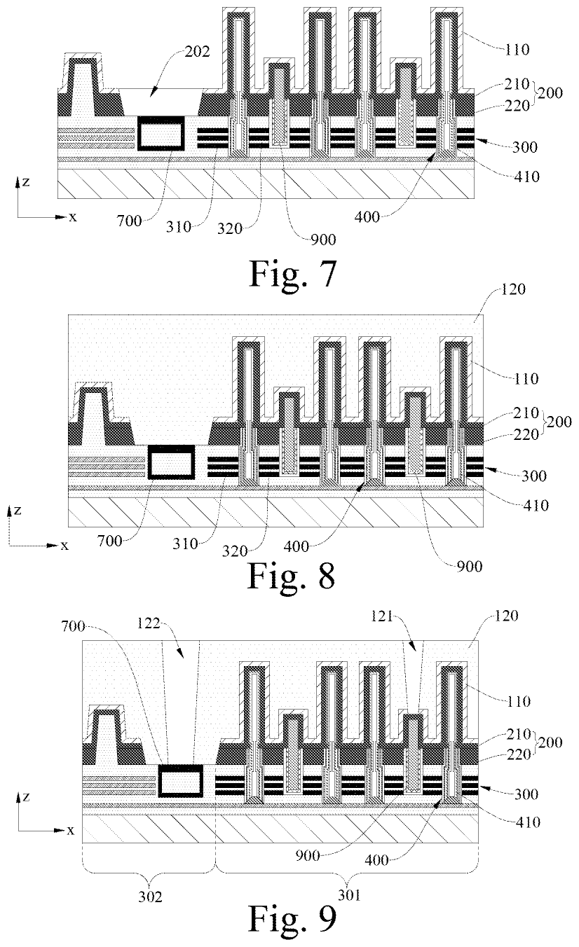

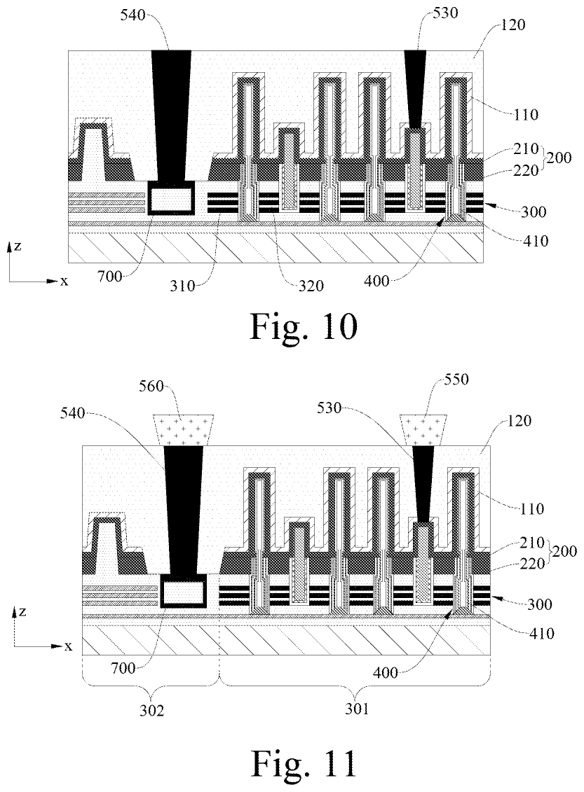

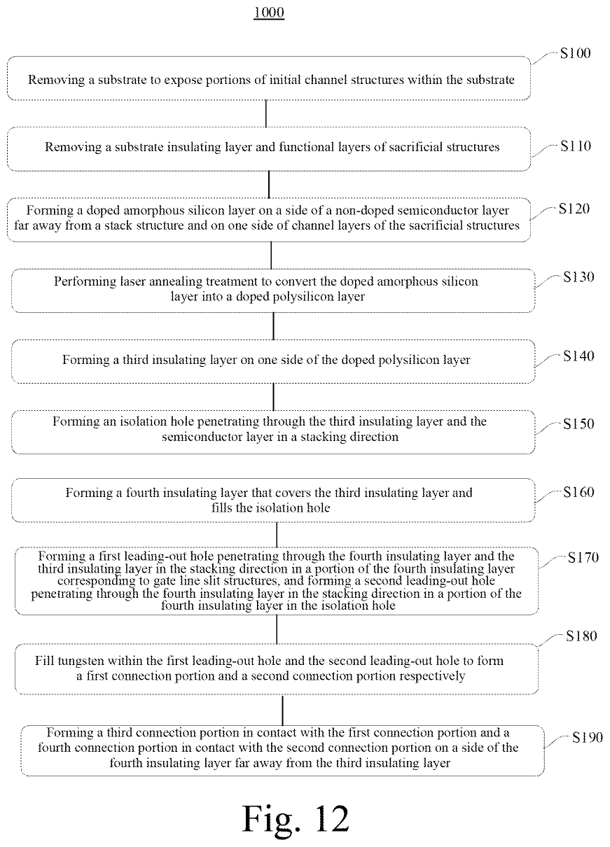

FIG. 12 illustrates a flow chart of a fabrication method of a semiconductor device according to one of implementations of the present application; as shown in FIG. 12, the fabrication method 1000 may include:
S100: a substrate 600 is removed to expose portions of initial channel structures 400′ within the substrate 600 (see FIGS. 1 and 2).
S110: a substrate insulating layer 610 and functional layers 420 of sacrificial structures 401 are removed to expose a side of a non-doped semiconductor layer 220 far away from a stack structure 300 and channel layers 410 of the sacrificial structures 401 (see FIGS. 2 and 3).
S120: a doped amorphous silicon layer 230 is formed on the side of the non-doped semiconductor layer 220 far away from the stack structure 300 and one side of the channel layers 410 of the sacrificial structures 401 (see FIGS. 3 and 4), wherein the doped amorphous silicon layer 230 may be formed on the one side of the non-doped semiconductor layer 220 and the channel layers 410 by a thin film deposition process. The above thin film deposition process may be, but not limited to, a physical vapor deposition (PVD) process, a chemical vapor deposition (CVD) process, an atomic layer deposition (ALD) process, or a combination of any of the above processes. Considering that a bonding process is a low-temperature process in the relevant art, the doped amorphous silicon layer 230 are preferably grown on the one side of the non-doped semiconductor layer 220 and the channel layers 410 using an atomic layer deposition (ALD) process at about 400° C. in the implementations of the present application.
S130: a laser annealing treatment is performed to convert the doped amorphous silicon layer 230 into a doped polysilicon layer (see FIGS. 4 and 5). At that time, the doped polysilicon layer converted by thermal treatment, i.e., a doped semiconductor layer 210, and the non-doped semiconductor layer 220 form a semiconductor layer 200 together.
S140: a third insulating layer 110 is formed on one side of the doped polysilicon layer to fill partial gaps between remaining portions of the sacrificial structures 401 and gate line slit structures 900 and partial gaps between remaining portions of two adjacent ones of the sacrificial structures 401 (see FIGS. 5 and 6).
S150: an isolation hole 202 penetrating through the third insulating layer 110 and the semiconductor layer 200 in a stacking direction is formed to expose one side of a word line connection portion 700 (FIGS. 6 and 7).
S160: a fourth insulating layer 120 that covers the third insulating layer 110 and fills the isolation hole 202 is formed (see FIGS. 7 and 8). The fourth insulating layer 120 may be formed by a thin film deposition process. Furthermore, after the fourth insulating layer 120 is formed by the thin film deposition process, a part of the fourth insulating layer 120 may be also removed using a chemical mechanical polishing (CMP) process to cause a side of the fourth insulating layer 120 far away from the third insulating layer 110 to form a flat surface (see FIG. 8).
S170: a first connection hole 121 penetrating through the fourth insulating layer 120 and the third insulating layer 110 in the stacking direction is formed in a portion of the fourth insulating layer 120 corresponding to the gate line slit structure 900 (see FIGS. 8 and 9); and a second connection hole 122 penetrating through the fourth insulating layer 120 in the stacking direction is formed in a portion of the fourth insulating layer 120 within the isolation hole 202 (see FIGS. 7 and 9).
S180: tungsten is filled within the first connection hole 121 and the second connection hole 122 to form a first connection portion 530 and a second connection portion 540 respectively (see FIGS. 9 and 10).
S190: a third connection portion 550 in contact with the first connection portion 530 and a fourth connection portion 560 in contact with the second connection portion 540 are formed on a side of the fourth insulating layer 120 far away from the third insulating layer 110 (see FIGS. 10 and 11), material of the third connection portion 550 and the fourth connection portion 560 is aluminum.

The core region 301 is full of the initial channel structures 400′, and spacings between individual initial channel structures 400′ are very small, while individual initial channel structures 400′ are different in depth in the stacking direction, which in turn results in different heights of the exposed channel layers 410 after the partial functional layers 420 of individual initial channel structures 400′ are removed, portions of the semiconductor layer 200 formed on the above channel layers 410 are obviously different in height, so that there are only certain spaces on the side of the gate line slit structures 900 far away from the stack structure 300, therefore the first connection hole 121 can only be formed in the portion of the fourth insulating layer 120 corresponding to the gate line slit structure 900, but the space here is still smaller, which limits an overlapping window, and results in higher process difficulty (see FIGS. 8 and 9).

In addition, to cause a side of the fourth insulating layer 120 far away from the semiconductor layer 200 to form a flat surface, the thicker fourth insulating layer 120 is required to be deposited on one side of the third insulating layer 110, and the thickness of a portion of the fourth insulating layer 120 in the periphery region 302 is much greater than that of a portion of the fourth insulating layer 120 in the core region 301 (see FIG. 8). This will not only significantly increase the difficulty of the CMP process in step S160, but also will result in greater hole depths and larger aspect ratios of the first connection hole 121 and the second connection hole 122 in the stacking direction, which in turn causes that aluminum cannot be directly filled due to the limitation of the state of the art, and limits a type of a filling material, so that tungsten is required to be first filled in the first connection hole 121 and the second connection hole 122 respectively, and then the third connection portion 550 in contact with the first connection portion 530 and the fourth connection portion 560 in contact with the second connection portion 540 are formed on the fourth insulating layer 120 using aluminum in the relevant art (see FIG. 11). Thus, the complexity and cost of a lead process are increased.

Furthermore, since individual initial channel structures 400′ are different in depth in the stacking direction, the exposed channel layers 410 after the partial functional layers 420 of individual initial channel structures 400′ are removed are different in height, so that the doped amorphous silicon layer 230 formed on the above channel layers 410 is uneven, while the initial channel structures 400′ have very small dimensions perpendicular to the stacking direction, thus sharp corners are prone to be present at portions of the doped amorphous silicon layer 230 formed on the channel layers 410. However, since a temperature of a laser annealing process is as high as 1,400° C.-1,500° C., and a bonding interface cannot be subjected to high temperature baking directly, the laser annealing process in step S130 can only lead to quick crystallization on the surface of the doped amorphous silicon layer 230, while the doped amorphous silicon layer 230 formed on the above channel layers 410 is uneven and the sharp corners are prone to be present therein, which very easily results in melting, collapse and even rupture of the portions of the doped amorphous silicon layer 230 formed on the channel layers 410 during laser annealing, and also easily leads to nonuniform crystallization of the doped amorphous silicon layer 230 at the same time.

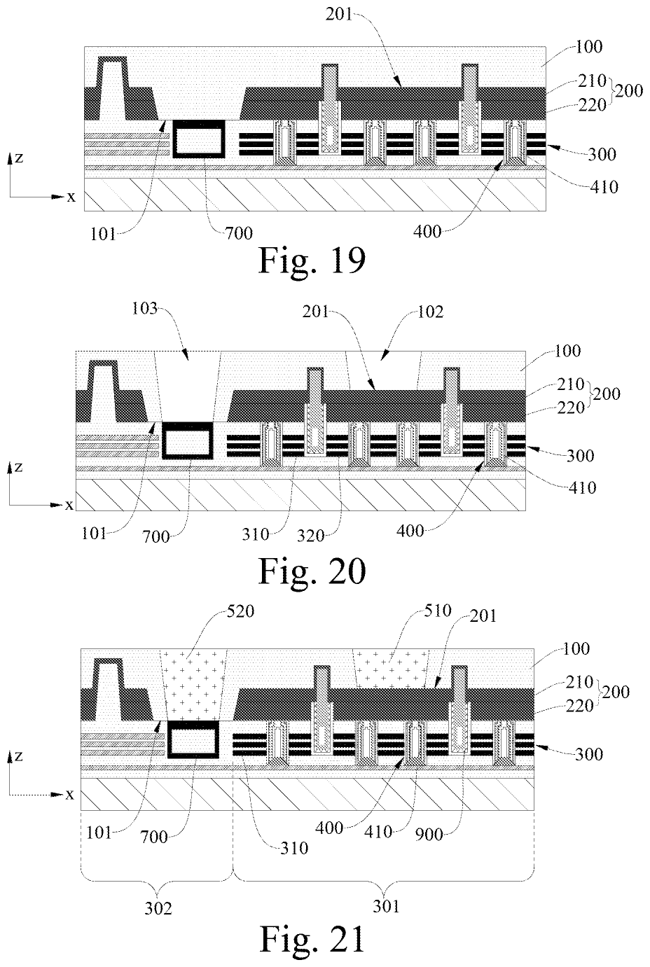

To at least solve part of the above problems, the implementations of the present application provide another fabrication method of a semiconductor device. FIG. 23 illustrates a flow chart of a fabrication method of a semiconductor device of another implementation of the present application; as shown in FIG. 23, the fabrication method 2000 can include:
S210: a first insulating layer 100 is formed on one side of an intermediate semiconductor device 800 (see FIGS. 17 and 19), wherein, as shown in FIG. 17, the intermediate semiconductor device 800 comprises a stack structure 300 and a semiconductor layer 200 on one side of the stack structure 300 in a stacking direction of the stack structure 300, the stack structure 300 comprises a core region 301 in which a plurality of channel structures 400 are formed, the channel structures 400 extend to the semiconductor layer 200, and projections of the semiconductor layer 200 and the channel structures 400 in a plane parallel to the stacking direction do not overlap, the first insulating layer 100 is at least formed on a first surface 201 of the semiconductor layer 200 far away from the stack structure 300.
S220: a first leading-out portion 510 that penetrates through the first insulating layer 100 in the stacking direction, i.e., a z direction, and is in contact with the semiconductor layer 200 is formed in a portion of the first insulating layer 100 corresponding to the core region 301 (see FIG. 21).

Since the projections of the semiconductor layer 200 and the channel structures 400 of the intermediate semiconductor device 800 adopted by the present application in the plane parallel to the stacking direction do not overlap, in other words, the side of individual channel structures 400 facing towards the semiconductor layer 200 substantially keeps flush, and portions of the semiconductor layer 200 formed on the channel structures 400 are also substantially flush by forming the first insulating layer 100 at least on the first surface 201 of the semiconductor layer 200 far away from the stack structure 300 and forming the first leading-out portion 510 in contact with the semiconductor layer 200 in the portion of the first insulating layer 100 corresponding to the core region 301, the present application not only can remove the restriction for a formation location of the first leading-out portion 510 due to different depths of individual initial channel structures 400′ to enable the first leading-out portion 510 to be formed in any location of the first insulating layer 100 corresponding to the core region 301, without being limited to locations corresponding to gate line slit structures 900, thereby reducing process difficulty and increasing an overlapping window, but also can significantly reduce the difficulty of a subsequent CMP process. Furthermore, since the projections of the semiconductor layer 200 and the channel structures 400 in the plane parallel to the stacking direction do not overlap, that is, the portions of the semiconductor layer 200 formed on the channel structures 400 are substantially flush, the present application may form the thinner first insulating layer 100 on the first surface 201 of the semiconductor layer 200 far away from the stack structure 300, while the first leading-out portion 510 is formed in the first insulating layer 100, so that an aspect ratio of the first leading-out portion 510 is decreased, a scope of selectable materials of the first leading-out portion 510 is expanded, and directly forming the first leading-out portion 510 with aluminum becomes possible, which in turn omits a tungsten filling process, thereby reducing the complexity and cost of a lead process. As can be seen, the first leading-out portion 510 in the implementations of the present application can replace the first connection portion 530 and the third connection portion 550.

It should be noted that, “the projections of the semiconductor layer 200 and the channel structures 400 in the plane parallel to the stacking direction do not overlap” above generally refers to that the side of individual channel structures 400 facing towards the semiconductor layer 200 substantially keeps flush, which should not be interpreted in an idealized or overly formal sense; in other words, slight overlapping of the projections of the semiconductor layer 200 and the channel structures 400 in the plane parallel to the stacking direction due to a process error should also fall in the scope claimed by the present application.

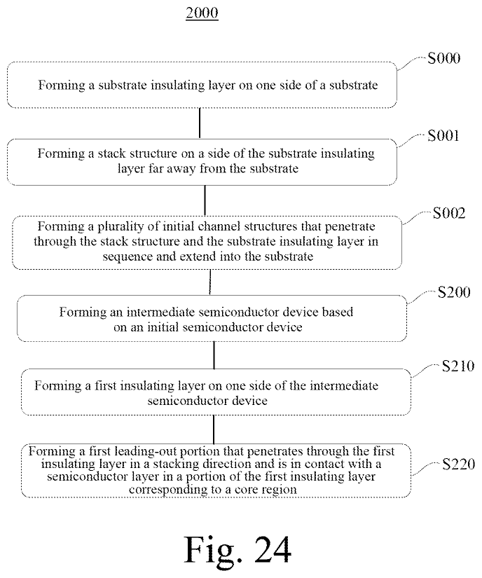

In addition, before performing step S210, as shown in FIG. 24, the fabrication method further includes: S200: the intermediate semiconductor device 800 is formed based on an initial semiconductor device 800′ (see FIGS. 1 and 17), wherein the initial semiconductor device 800′ includes a plurality of initial channel structures 400′, a stack structure 300, as well as a substrate insulating layer 610 and a substrate 600 that are disposed in sequence in the stacking direction of the stack structure 300, the initial channel structures 400′ penetrate through the stack structure 300 and the substrate insulating layer 610 in sequence and extend into the substrate 600, the channel structures 400 includes portions of the initial channel structures 400′ in the stack structure 300.

Further, as shown in FIG. 24, before performing step S200, the method further comprises a step of forming the initial semiconductor device 800′; particularly, the method further includes: S000: a substrate insulating layer 610 is formed on one side of a substrate 600; S001: a stack structure 300 is formed on a side of the substrate insulating layer 610 far away from the substrate 600; and S002: a plurality of initial channel structures 400′ that penetrate through the stack structure 300 and the substrate insulating layer 610 in sequence and extend into the substrate 600 are formed.

Various steps in the method of fabricating the semiconductor device in the implementations of the present application are introduced below in details.

### Step S000

As shown in FIG. 1, a substrate insulating layer 610 is formed on one side of a substrate 600. The substrate insulating layer 610 may be, but not limited to, a silicon oxide layer, a silicon nitride layer or a silicon oxynitride layer. As an example, the thickness of the substrate insulating layer 610 is not less than 600 Å, for example, the thickness of the substrate insulating layer 610 is 600 Å, 650 Å, or 700 Å in the implementations of the present application. The “thickness of the substrate insulating layer 610” generally refers to a spacing between a side of the substrate insulating layer 610 facing towards the substrate 600 and a side of the substrate insulating layer 610 far away from the substrate 600 in a stacking direction of a stack structure 300, i.e., a z direction.

In addition, it should be noted that, the substrate 600 may be a substrate fabricated currently, that is, the method further comprises a step of fabricating the substrate 600 before performing step S000, and certainly, an existing substrate may also be directly used, that is, the method may also omit the step of fabricating the substrate 600. The substrate 600 may be either a single-layer structure, or a multi-layer structure. For example, the substrate 600 is a single-layer structure fabricated by a semiconductor material. The semiconductor material may be, but not limited to, monocrystalline silicon (Si), monocrystalline germanium (Ge), silicon germanium (GeSi), silicon carbide (SiC), silicon on insulator (SOI), germanium on insulator (GOI), or III-V compounds, such as gallium arsenide, etc. As an example, the substrate 600 is a monocrystalline silicon layer.

For another example, the substrate 600 is a multi-layer structure, and at least two layers have different materials, the substrate 600 may use, for example, a physical vapor deposition (PVD) process, a chemical vapor deposition (CVD) process, an atomic layer deposition (ALD) process, or a combination of any of the above processes. In the event that the substrate 600 is the multi-layer structure, the substrate 600 may comprise a substrate sacrificial layer. The substrate sacrificial layer may use multiple structure forms: for example, the substrate sacrificial layer comprises at least one of a silicon oxide layer, a silicon nitride layer and a silicon oxynitride layer. For another example, the substrate sacrificial layer comprises a dielectric layer, a sacrificial layer and a dielectric layer that are disposed in sequence, wherein the dielectric layers may be silicon nitride layers, the sacrificial layer may be a silicon oxide layer. For yet another example, the substrate sacrificial layer comprises at least one of a dielectric layer, a semiconductor layer and a conductive layer. Furthermore, the substrate 600 may further include a buffer layer formed on one side of the substrate sacrificial layer. As an example, the buffer layer includes at least one of a dielectric layer, a semiconductor layer and a conductive layer. For example, the buffer layer is a polysilicon layer. Certainly, an ion implantation or diffusion process may also be used to form well regions formed by doping an N-type or P-type dopant in part of a region of the substrate 600. The dopant may include at least one of phosphorus (P), arsenic (As) and antimony (Sb). It should be noted that, the well regions may be fabricated either by selecting the same dopant, or by selecting different dopants, doping concentrations of the various well regions may be either the same or different, to which the present application does not impose limitations.

### Step S001

Continuing with reference to FIG. 1, a stack structure 300 may be formed on a side of the substrate insulating layer 610 far away from the substrate 600; particularly, a laminated structure is formed on the side of the substrate insulating layer 610 far away from the substrate 600, wherein the laminated structure includes sacrificial layers and second insulating layers 320 which are stacked alternately; the sacrificial layers are replaced by gate layers 310 to form the stack structure 300.

The laminated structure may be formed on one side of the substrate insulating layer 610 by a thin film deposition process, which may be, but not limited to, a physical vapor deposition (PVD) process, a chemical vapor deposition (CVD) process, an atomic layer deposition (ALD) process, or a combination of any of the above processes. In some implementations, the laminated structure may comprise the sacrificial layers and the second insulating layers 320 that are disposed in pairs. As an example, the laminated structure may include, but not limited to, 64 pairs of, 128 pairs of, or more than 128 pairs of sacrificial layers and second insulating layers 320, the second insulating layers 320 may be silicon oxide layers, the sacrificial layers may be silicon nitride layers. The silicon oxide layers plays a role of isolation, the silicon nitride layers may be replaced by the gate layers 310 in a subsequent process.

It should be noted that, the above mainly describes a fabrication method of a single laminated structure, that is, it is directed to the case that the number of stack layers of the laminated structure is smaller; however, with an increasing memory capacity of a three-dimensional memory, the number of stack layers of the laminated structure is also increasing; the semiconductor device is often fabricated using a dual stack technology or a multi-stack technology in the relevant art, that is, a plurality of sub-laminated structures are stacked in sequence on the side of the substrate insulating layer 610 far away from the substrate 600 in a direction far away from the substrate 600 to form the laminated structure. Each sub-laminated structure comprises a plurality of sacrificial layers and second insulating layers 320 which are disposed in an alternate stack-up manner. The number of layers of individual sub-laminated structures may be the same or different. However, considering that the fabrication method of the single laminated structure can be completely or partially applicable to multiple sub-laminated structures, the contents relevant or similar thereto will not be repeated.

### Step S002

Continuing with reference to FIG. 1, forming a plurality of initial channel structures 400′ that penetrate through the stack structure 300 and the substrate insulating layer 610 in sequence and extend into the substrate 600 specifically comprises:
forming a plurality of channel holes that penetrate through the stack structure 300 and the substrate insulating layer 610 in sequence and extend into the substrate 600, wherein in the light of the problem of lateral under etching present in wet etching, the channel holes may be formed by a dry etching process, a combination of dry and wet etching processes or a patterning process, wherein the patterning process includes lithography, cleaning and a chemical mechanical polishing process. Cross sectional shapes of the channel holes, i.e., sectional shapes of the channel holes perpendicular to the stacking direction, may be, but not limited to, round, elliptic or polygonal. As an example, the step of forming the channel holes may comprise: forming a mask layer on a side of the stack structure 300 far away from the substrate insulating layer 610, wherein the mask layer defines a cross sectional image of the channel holes, the mask layer may be, but not limited to, a silicon nitride layer or a titanium nitride layer; etching the channel holes at locations where the mask layer defines cross sectional patterns of the channel holes using a plasma dry etching process; and removing the mask layer.

Functional layers 420 and channel layers 410 are formed in sequence on inner walls of the channel holes, wherein both the functional layers 420 and the channel layers 410 may be formed using a thin film deposition process, which may be, but not limited to, a physical vapor deposition (PVD) process, a chemical vapor deposition (CVD) process, an atomic layer deposition (ALD) process, or a combination of any of the above processes. As an example, the step of forming the functional layers 420 and the channel layers 410 may comprise: forming blocking layers on the inner walls of the channel holes to block outflow of charge; forming charge trap layers on a side of the blocking layers far away from the inner walls of the channel holes to store the charge; forming tunneling layers on a side of the charge trap layers far away from the blocking layers; forming the channel layers 410 on a side of the tunneling layers far away from the charge trap layers to transport the required charge, i.e., electrons or holes. The blocking layers and the tunneling layers may be, but not limited to, oxidation layers, the charge trap layers may be, but not limited to, nitride layers, that is, the functional layers 420 comprise ONO structures, the channel layers 410 may be, but not limited to, amorphous silicon layers, polysilicon layers or monocrystalline silicon layers. It should be noted that, those skilled in the art should understand that, without departing from the teachings of the present application, the formation locations of the functional layers 420 on the inner walls of the channel holes may be controlled according to different semiconductor device architectures, that is, the functional layers 420 may be either formed on sidewalls and bottom surfaces of the channel holes, or may be only formed on the sidewalls of the channel holes, to which the present application does not impose limitations.

Dielectric layers 430 are filled in pores surrounded by the channel layers 410, wherein the dielectric layers 430 may be formed using a channel filling process, the dielectric layers 430 may be, but not limited to, silicon oxide layers. Furthermore, to reduce structure pressure, a plurality of insulating gaps may be formed in the dielectric layers 430 by controlling respective parameters of the channel filling process during the formation of the dielectric layers 430.

channel plugs electrically connected with the channel layers 410 are formed at an end of the dielectric layers 430 far away from the substrate 600, wherein a material of the channel plugs may be the same as a material of the channel layers 410.

As can be seen from the above, cross sectional dimensions of the initial channel structures 400′ formed by using the above steps are substantially the same in the stacking direction. Portions of the initial channel structures 400′ are located in the substrate 600 and the substrate insulating layer 610, and another portions thereof are located in the stack structure 300. For ease of description, portions of the initial channel structures 400′ in the substrate 600 and the substrate insulating layer 610 may be referred to as sacrificial structures 401, and portions of the initial channel structures 400′ in the stack structure 300 may be referred to as channel structures 400.

Certainly, considering that the portions of the initial channel structures 400′ in the substrate 600 and the substrate insulating layer 610 (i.e., the sacrificial structures 401) need to be removed in a subsequent process, in order to prevent grinding fluid or etching fluid from entering into the channel structures 400, before the functional layers 420 and the channel layers 410 are formed on the inner walls of the channel holes in sequence, narrowed layers may also be formed on surfaces of the channel holes to facilitate enclosing the channel structures 400 based on the narrowed layers after removing the sacrificial structures 401 subsequently. Particularly, before performing step S001, i.e., before forming the stack structure 300 on the side of the substrate insulating layer 610 far away from the substrate 600, the fabrication method further includes: forming a non-doped semiconductor layer 220 on the side of the substrate insulating layer 610 far away from the substrate 600 (see FIG. 1), wherein the stack structure 300 may be formed on a side of the non-doped semiconductor layer 220 far away from the substrate insulating layer 610. Thus, the step of forming the initial channel structures 400′ may include: forming channel holes that penetrate through the stack structure 300, the non-doped semiconductor layer 220 and the substrate insulating layer 610 in sequence and extend into the substrate 600; forming narrowed layers based on a surface of the non-doped semiconductor layer 220 exposed to the channel holes, apertures of narrowed holes surrounded by the narrowed layers being less than those of the channel holes; forming the functional layers 420 and the channel layers 410 on the inner walls of channels and the surfaces of the narrowed layers in sequence; filling the dielectric layers 430 in the pores surrounded by the channel layers 410, and forming the channel plugs electrically connected with the channel layers 410 at the end of the dielectric layers 430 far away from the substrate 600.

As can be seen from the above, the cross sectional dimensions of the initial channel structures 400′ formed by using the above steps are not the same in the stacking direction, part of the initial channel structures 400′ is located in the substrate 600 and the substrate insulating layer 610, part of the initial channel structures 400′ is located in the non-doped semiconductor layer 220, and another part of the initial channel structures 400′ is located in stack structure 300, the cross sectional dimensions of the portions of the initial channel structures 400′ in the non-doped semiconductor layer 220 are minimum. For ease of description, as shown in FIG. 1, portions of the initial channel structures 400′ in the substrate 600 and the substrate insulating layer 610 may be referred to as sacrificial structures 401, portions of the initial channel structures 400′ in the non-doped semiconductor layer 220 may be referred as narrowed structures 402, and portions of the initial channel structures 400′ in the stack structure 300 are referred as channel structures 400, the cross sectional dimensions of the narrowed structures 402 are smaller than the cross sectional dimensions of the sacrificial structures 401 and the channel structures 400, that is, in a plane perpendicular to the stacking direction, projection area of the narrowed structures 402 is smaller than projection area of the sacrificial structures 401 and the channel structures 400.

As an example, the narrowed layers may be formed by oxidizing part of the non-doped semiconductor layer 220 exposed to the channel holes; in other words, the narrowed layers may be oxidation layers in the implementations of the present application. Based on an oxidation principle, growth of the narrowed layers during oxidation needs to consume the non-doped semiconductor layer 220, that is, the non-doped semiconductor layer 220 needs to be consumed by a thickness of y when the narrowed layers are grown by a thickness of x, wherein x is greater than y. Thus, during the oxidation, with the growth of the narrowed layers, the narrowed layer will protrude into the channel holes gradually, so that the apertures of the narrowed holes surrounded by the narrowed layers are smaller than those of the channel holes. The narrowed layers may be annular convex structures, growth speeds of the narrowed layers in the stacking direction are substantially the same; in other words, the apertures of the narrowed holes are substantially the same in the stacking direction. Certainly, during an actual process, the growth speeds of the narrowed layers in the stacking direction may be different. For example, oxidation rate at the two ends of the narrowed layers in the stacking direction is smaller than oxidation rate at the middle of the narrowed layers, so that the side of the narrowed layers far away from the non-doped semiconductor layer 220 presents as arc surface that is convex in a radial direction of the channel holes and a direction far away from the non-doped semiconductor layer 220. In this case, the narrowed holes surrounded by the narrowed layers are similar to a hourglass in shape; the apertures of the narrowed holes are first decreased gradually in a direction approaching the substrate 600 and then increased gradually; in other words, the narrowed holes comprise convergent holes and divergent holes that are communicated in sequence in the direction approaching the substrate 600. As their names suggest, the convergent holes mean that their apertures are gradually decreased in the direction approaching the substrate 600, the divergent holes mean that their apertures are gradually increased in the direction approaching the substrate 600, locations where the narrowed holes have the minimum aperture are generally at connections between the convergent holes and the divergent holes.

It should be noted that, when the substrate 600 is a polysilicon layer, during the formation of the narrowed layers using an oxidation process, for example, a wet-oxygen oxidation process, portions of the substrate 600 exposed to the inside of the channel holes will also be oxidized to form oxidation layers. Furthermore, those skilled in the art should understand that forming the narrowed layers by the oxidation process is merely an example, the narrowed layers may be formed by any other suitable processes, without departing from the teachings of the present application.

### Step S200

Forming the intermediate semiconductor device 800 based on the initial semiconductor device 800′ particularly comprises: removing the substrate 600 to expose the portions of the initial channel structures 400′ in the substrate 600 (see FIGS. 1 and 2); removing the substrate insulating layer 610 and the exposed portions of the initial channel structures 400′ (see FIG. 14); forming the semiconductor layer 200 (see FIG. 17).

As can be seen from the above step S002, the cross sectional dimensions of the initial channel structures 400′ may be substantially the same or different in the stacking direction. For the initial channel structures 400′ of the two different structure forms, the specific steps of forming the intermediate semiconductor device 800 based on the initial semiconductor device 800′ are different, specifically:

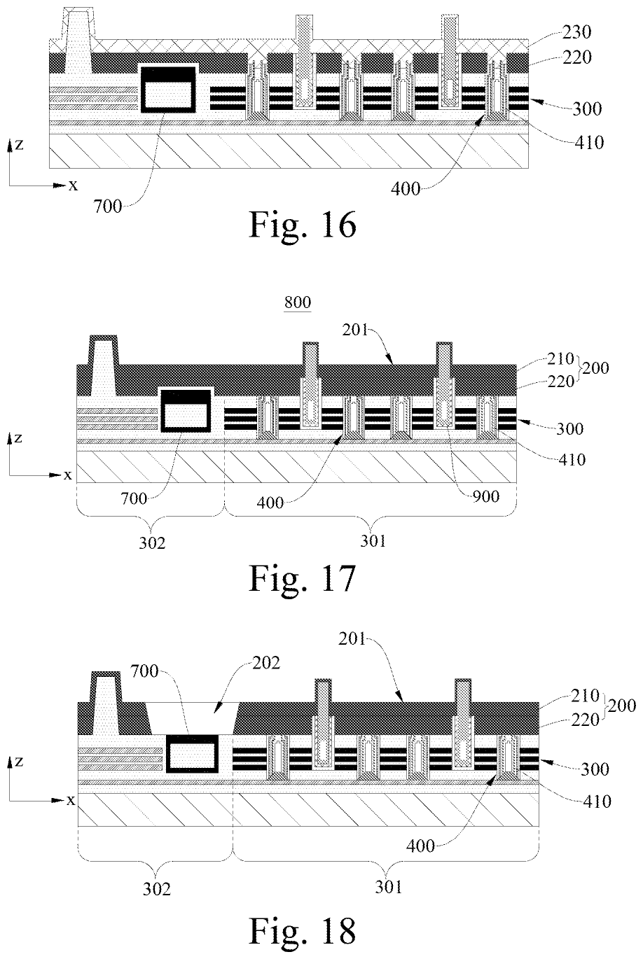

Circumstance I: under the circumstance that the cross sectional dimensions of the initial channel structures 400′ are different in the stacking direction, that is, under the circumstance that the initial channel structures 400′ comprise the sacrificial structures 401 located in the substrate 600 and the substrate insulating layer 610, the narrowed structures 402 located in the non-doped semiconductor layer 220, and channel structures 400 located in the stack structure 300, step S200 may comprise: removing the substrate 600 to expose the portions of the initial channel structures 400′ in the substrate 600 (see FIGS. 1 and 2); removing the substrate insulating layer 610 and the functional layers 420 of the sacrificial structures 401 to expose a side of the non-doped semiconductor layer 220 far away from the stack structure 300 and the channel layers 410 of the sacrificial structures 401 (see FIGS. 2 and 3); removing the channel layers 410 and the dielectric layers 430 of the sacrificial structures 401 to expose part of the narrowed structures 402; filling isolation insulating layers 440 in first gaps surrounded by the dielectric layers 430 of the narrowed structures 402 to enclose the first gaps (see FIG. 15). A doped amorphous silicon layer 230 is formed on a side of the non-doped semiconductor layer 220 far away from the stack structure 300 (see FIG. 16); and a thermal treatment is performed to convert the doped amorphous silicon layer 230 into a doped polysilicon layer (see FIG. 17), wherein the semiconductor layer 200 comprises the doped polysilicon layer and the non-doped semiconductor layer 220.

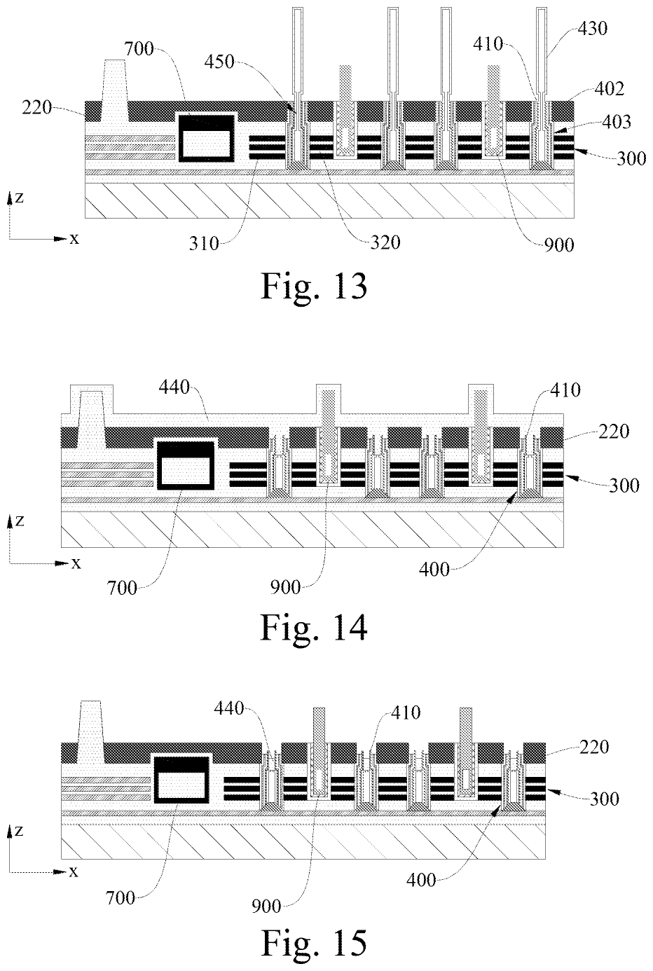

The channel layers 410 and the dielectric layers 430 of the sacrificial structure 401 may be removed synchronously using low-selectivity etching fluid, or may be removed in two steps. As an example, removing the channel layers 410 and the dielectric layers 430 of the sacrificial structures 401 may include: removing the channel layers 410 of the sacrificial structures 401 to expose the dielectric layers 430 of the sacrificial structures 401 (see FIG. 13); removing the dielectric layers 430 of the sacrificial structures 401 to expose part of the narrowed structures 402. It should be noted that, in the stacking direction, the removed lengths of the functional layers 420, the channel layers 410 and the dielectric layers 430 may be different, for example, the removed lengths of the channel layers 410 may be slightly less than the removed length of the functional layers 420 and the dielectric layers 430; in other words, after removing the exposed portions of the initial channel structures 400′, the channel layers 410 protrude from the functional layers 420 and the dielectric layers 430 in the stacking direction. Such a configuration can increase contact area of the channel layers 410 with the doped polysilicon layer formed subsequently to facilitate subsequent process connection. In addition, during the removal of the channel layers 410, part of the non-doped semiconductor layer 220 may also be removed. However, since the thickness of the non-doped semiconductor layer 220 in the stacking direction is generally greater than the thickness of the channel layers 410, the non-doped semiconductor layer 220 of a certain thickness is still remained on one side of the stack structure 300 after removing the channel layers 410 of the sacrificial structures 401; in other words, the non-doped semiconductor layer 220 is thinned to some extent.

In addition, it should also be noted that, the removed depths of the initial channel structures 400′ may be controlled by adjusting a concentration of the etching fluid or an etching duration, or setting respective stop layers in the implementations of the present application. For example, only the portions of the initial channel structures 400′ in the substrate 600 and the substrate insulating layer 610 may be removed, that is, only the sacrificial structures 401 are removed, the non-doped semiconductor layer 220 serves as a stop layer of the etching process. Certainly, in addition to the removal of the sacrificial structures 401, part of the narrowed structures 402 may also be removed to expose the inner walls of part of the narrowed holes.

In some implementations, filling the isolation insulating layers 440 in the first gaps surrounded by the dielectric layers 430 of the narrowed structures 402 to enclose the first gaps may comprise: forming the isolation insulating layers 440 on a side of the non-doped semiconductor layer 220 far away from the stack structure 300 to cover a surface of the non-doped semiconductor layer 220 far away from the stack structure 300 and fill the first gaps (see FIG. 14); at least removing portions of the isolation insulating layers 440 covering the surface of the non-doped semiconductor layer 220 far away from the stack structure 300 to cause the remaining isolation insulating layers 440 to enclose the first gaps (see FIG. 15). As can be seen from the above step of forming the initial channel structures 400′, before forming the functional layers 420 and the channel layers 410 in sequence on the inner walls of the channel holes, the narrowed layers (not shown in the figures) may also be formed based on the surface of the non-doped semiconductor layer 220 exposed to the channel holes. Since the apertures of the narrowed holes surrounded by the narrowed layers are smaller than those of the channel holes, the cross sectional dimensions of the narrowed structures 402 formed here subsequently are much smaller than those of the sacrificial structures 401 and the channel structures 400. Thus, after removing the channel layers 410 and the dielectric layers 430 of the sacrificial structures 401, the first gaps surrounded by the dielectric layers 430 are exposed; however, the apertures of the first gaps are very small, so that the first gaps will be quickly enclosed by part of the isolation insulating layers 440 during depositing the isolation insulating layers 440 on the side of the non-doped semiconductor layer 220 far away from the stack structure 300. Then, the portions of the isolation insulating layers 440 covering the surface of the non-doped semiconductor layer 220 far away from the stack structure 300 are removed, the portions of the isolation insulating layers 440 in the first gaps may block the grinding fluid or etching fluid in the subsequent process from entering the first gaps.

Circumstance II: under the circumstance that the cross sectional dimensions of the initial channel structures 400′ are substantially the same in the stacking direction, that is, under the circumstance that the initial channel structures 400′ comprise the sacrificial structures 401 located in the substrate 600 and the substrate insulating layer 610, and the channel structures 400 located in the stack structure 300, step S200 may comprise: removing the substrate 600 to expose the portions of the initial channel structures 400′ in the substrate 600; removing the substrate insulating layer 610 and the functional layers 420 of the sacrificial structures 401 to expose one side of stack structure 300 and the channel layers 410 of the sacrificial structures 401; at least removing the channel layers 410 and the dielectric layers 430 of the sacrificial structures 401 to expose part of the channel structures 400; and filling the isolation insulating layers 440 within second gaps surrounded by the dielectric layers 430 of the channel structures 400 to enclose the second gaps. The doped amorphous silicon layer 230 is formed on one side of the stack structure 300; and a thermal treatment is performed to convert the doped amorphous silicon layer 230 into a doped polysilicon layer, wherein the semiconductor layer 200 comprises the doped polysilicon layer.

It should be noted that, since the cross sectional dimensions of the initial channel structures 400′ in the circumstance II are substantially the same in the stacking direction, the apertures of the second gaps are obviously greater than those of the first gaps in the circumstance I, thereby the thicker isolation insulating layers 440 need to be deposited on one side of the stack structure 300 so that the second gaps can be enclosed; however, when the portions of the isolation insulating layers 440 covering the surface of the stack structure 300 are removed after the isolation insulating layers 440 are formed, the second gaps are very easy to open again due to the relatively thicker isolation insulating layers 440, so that the process difficulty of filling the second gaps is relatively higher. As can be seen, the presence of the narrowed structures 402 in the circumstance I can reduce the difficulty of the above filling process. Certainly, the implementations of the present application may also omit the step of filling the isolation insulating layers 440. In this case, although the second gaps surrounded by the dielectric layers 430 of the channel structures 400 are exposed gradually during the removal of the channel layers 410 and the dielectric layers 430 of the sacrificial structures 401, and the etching fluid or the grinding fluid may enter the second gaps, studies find that entry of some etching fluid or grinding fluid, for example, HF acid fluid, into the second gaps does not affect the electrical performance of the entire semiconductor device.

It should be noted that, the following steps may be used to remove the substrate 600 in the above two circumstances: first performing rough grinding on a side of the substrate 600 far away from the substrate insulating layer 610 using a chemical mechanical polishing (CMP) process to thin the substrate 600; for example, thinning the thickness of the substrate 600 from about 700 ?m to about 7 ?m using the CMP process; then, etching the substrate 600 using lower-selectivity etching fluid to increase an etching rate; next, removing the remaining substrate 600 using higher-selectivity etching fluid, and taking the substrate insulating layer 610 as a stop layer of the etching process. Certainly, in addition to the above manner for removing the substrate 600, the substrate 600 may also be etched always using the lower-selectivity etching fluid, until the portions of the initial channel structures 400′ in the substrate 600 are exposed. Certainly, the former manner is higher in etching rate and lower in cost. Furthermore, in the above two circumstances, the thermal treatment process used for forming the semiconductor layer 200 may be, but not limited to, a laser annealing process. For the circumstance I, after the exposed portions of the initial channel structures 400′ are removed, the doped amorphous silicon layer 230 formed subsequently is in contact with the narrowed structures 402. During laser annealing, the narrowed structures 402, the doped amorphous silicon layer 230 and the non-doped semiconductor layer 220 are molten and crystallized together; in other words, after the laser annealing, the narrowed structures 402 form a whole together with the doped amorphous silicon layer 230 and the non-doped semiconductor layer 220 respectively, without an obvious interface detected.

As can be seen from the above, regardless of the circumstance I or the circumstance II, by removing part of the initial channel structures 400′ to cause the projections of the remaining initial channel structures 400′, i.e., the channel structures 400, and the semiconductor layer 200 in the plane parallel to the stacking direction not to overlap in the subsequent process, the present application not only can remove the restriction for the formation location of the first leading-out portion 510 due to different depths of individual channel structures 400 to enable the first leading-out portion 510 to be formed at any location of a first insulating layer 100 corresponding to the core region 301, without being limited to locations corresponding to the gate line slit structures 900 anymore, thereby reducing the process difficulty and increasing the overlapping window, but also can significantly reduce the difficulty of the subsequent CMP process, and can further cause the portions, of the doped polysilicon layer formed in the subsequent process, corresponding to the channel structures 400 to be substantially flush at the same time, thereby avoiding the situations such as melting, collapse and even rupture, etc. due to the uneven doped polysilicon layer and presence of sharp corners, etc. during the subsequent thermal treatment, and also avoiding the situation where crystallization of the doped amorphous silicon layer 230 is nonuniform.

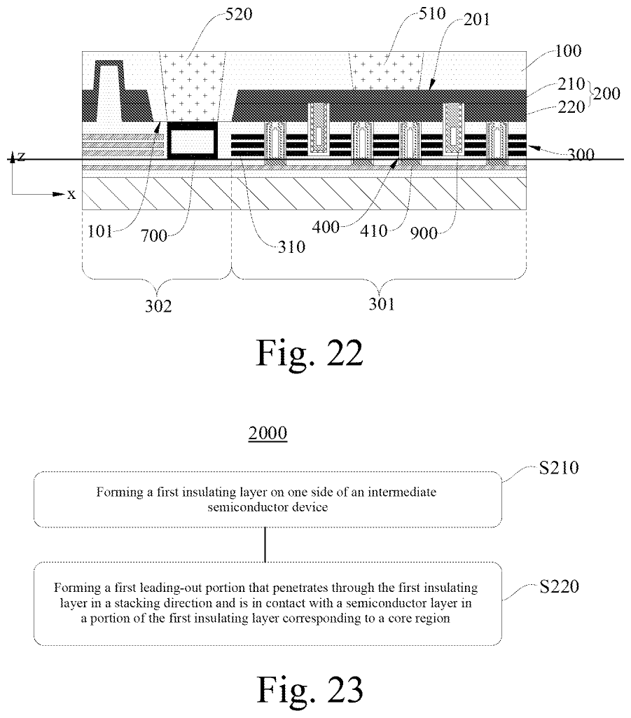

In some implementations, the initial semiconductor device 800′ further comprises a plurality of gate line slit structures 900 which penetrate through the stack structure 300 in the stacking direction, and extend in a first direction, i.e., a y direction, perpendicular to the stacking direction, wherein the y direction is perpendicular to the x direction and the z direction, and the z direction is the stacking direction. Thus, for the circumstance I, before forming the doped amorphous silicon layer 230 on the side of the non-doped semiconductor layer 220 far away from the stack structure 300, the fabrication method may further comprise: removing portions of the gate line slit structures 900 exposed to one side of the non-doped semiconductor layer 220 to cause portions of the non-doped semiconductor layer 220 on one side far away from the stack structure 300 and corresponding to the core region 301 to form a flat surface (see FIG. 22). Similarly, for the circumstance II, before forming the doped amorphous silicon layer 230 on one side of the stack structure 300, the fabrication method may further comprise: removing portions of the gate line slit structures 900 exposed to one side of the stack structure 300 to cause the portions on one side of the stack structure 300 and corresponding to the core region 301 to form a flat surface.

### Step S210

The first insulating layer 100 is formed on one side of the intermediate semiconductor device 800 (see FIGS. 17 and 19). The first insulating layer 100 may be formed on a first surface 201 of the semiconductor layer 200 by a thin film deposition process, and a material for forming the first insulating layer 100 may be, but not limited to, silicon dioxide, silicon nitride or other materials. The above thin film deposition process may be, but not limited to, a physical vapor deposition (PVD) process, a chemical vapor deposition (CVD) process, an atomic layer deposition (ALD) process, or a combination of any of the above processes. The thickness of a portion of the first insulating layer 100 in the core region 301 may be less than or equal to 1000 nm.

In some implementations, as shown in FIG. 17, the stack structure 300 further comprises a periphery region 302 on at least one side of the core region 301, the stack structure 300 comprises gate layers 310 and second insulating layers 320 that are alternately stacked in the stacking direction within the core region 301, the intermediate semiconductor device 800 further comprises a word line connection portion 700 that is located in the periphery region 302 and electrically connected with the gate layers 310. In this case, step S210 includes: forming an isolation hole 202 penetrating through the semiconductor layer 200 in the stacking direction in a portion of the semiconductor layer 200 corresponding to the word line connection portion 700 (see FIG. 18); forming the first insulating layer 100 that covers the first surface 201 and fills the isolation hole 202 (see FIG. 19). Thus, the formed first insulating layer 100 comprises a horizontal portion covering the first surface 201 and a convex portion 101 located in the isolation hole 202.

Since the projections of the semiconductor layer 200 and the channel structures 400 in the plane parallel to the stacking direction do not overlap, that is, the portions of the semiconductor layer 200 formed on the channel structures 400 are substantially flush, the present application only requires forming the thinner first insulating layer 100 so as to be capable of covering the first surface 201 and filling the isolation hole 202, and the thickness of a portion of the first insulating layer 100 in the periphery region has little difference from the thickness of a portion of the first insulating layer 100 in the core region 301. Thus, not only can the difficulty of planarizing the first insulating layer 100 using the CMP process subsequently be reduced, but also aspect ratios of the first leading-out portion 510 and a second leading-out portion 520 subsequently formed in the first insulating layer 100 can be reduced, a scope of selectable materials of the first leading-out portion 510 and the second leading-out portion 520 is expanded, and directly forming the first leading-out portion 510 and the second leading-out portion 520 with aluminum becomes possible, which in turn omits the tungsten filling process, thereby reducing the complexity and cost of the lead process.

### Step S220

A first leading-out portion 510 penetrating through the first insulating layer 100 in the stacking direction and being in contact with the semiconductor layer 200 is formed in a portion of the first insulating layer 100 corresponding to the core region 301 (see FIG. 21). A material of the first leading-out portion 510 may be, but not limited to, tungsten, a metal and/or a metal alloy less than 10 g/cm3 in density.

In some implementations, step S220 may include: forming a first leading-out hole 102 penetrating through the first insulating layer 100 in the stacking direction to expose part of the first surface 201 of the semiconductor layer 200 (see FIG. 20); filling a conductive material within the first leading-out hole 102 to form the first leading-out portion 510 (see FIG. 21). Since the projections of the semiconductor layer 200 and the channel structures 400 of the intermediate semiconductor device 800 used by the present application in the plane parallel to the stacking direction do not overlap, in other words, the side of individual channel structures 400 facing towards the semiconductor layer 200 substantially keeps flush, the portions of the semiconductor layer 200 formed on the channel structures 400 are also substantially flush, the thinner first insulating layer 100 may be formed in step S210, and the first leading-out hole 102 is formed in the first insulating layer 100, in other words, the thickness of the first leading-out hole 102 depends on the thickness of the first insulating layer 100, so that the first leading-out hole 102 may have a smaller aspect ratio, thus a scope of a conductive material for filling the first leading-out hole 102 is expanded, and directly filling the first leading-out hole 102 with aluminum becomes possible, which in turn omits the tungsten filling process, thereby reducing the complexity and cost of the lead process. In the implementations of the present application, the conductive material for filling the first leading-out hole 102 may be, but not limited to, tungsten, a metal and/or a metal alloy less than 10 g/cm3 in density.

As can be seen from the above, since the first leading-out hole 102 has a smaller aspect ratio, the first leading-out hole 102 may be filled directly with aluminum. Specifically, aluminum may be deposited on a side of the first insulating layer 100 far away from the semiconductor layer 200 using a thin film deposition process to cover the side of the first insulating layer 100 far away from the semiconductor layer 200 and fill the first leading-out hole 102; aluminum covering one side of the first insulating layer 100 is removed, wherein the aluminum within the first leading-out hole 102 constitutes the first leading-out portion 510. It should be noted that, a width of the first leading-out hole 102 perpendicular to the stacking direction is relatively larger in the present application, in other words, an inside space of the first leading-out hole 102 is larger, and more conductive materials are required to be filled, but the first leading-out hole 102 may be filled directly with the aluminum because it has a smaller aspect ratio, while the density of the aluminum is very low, only 2.7 g/cm3, so that the entire intermediate semiconductor device 800 will not be bent even if the thicker aluminum is deposited on one side of the first insulating layer 100 in order to completely fill the first leading-out hole 102. Certainly, the first leading-out hole 102 may be filled directly with tungsten in the present application; however, as compared with the aluminum, the tungsten is relatively higher in density, if the inside space of the first leading-out hole 102 is relatively larger, then the thicker tungsten is required to be deposited on one side of the first insulating layer 100, which may possibly bend the intermediate semiconductor device 800.

In some implementations, a width of the first leading-out portion 510 in a second direction, i.e., a width in an x direction, is 200 nm-1200 nm, wherein the x direction is perpendicular to the y direction and the z direction, the z direction is the stacking direction of the stack structure 300.

In some implementations, the fabrication method further includes: forming a second leading-out hole 103 penetrating through the first insulating layer 100 in the stacking direction to expose the word line connection portion 700 in a portion of the first insulating layer 100 in the isolation hole 202 (see FIG. 20); filling a conductive material in the second leading-out hole 103 to form the second leading-out portion 520 (see FIG. 21). Since the present application may form the first insulating layer 100 with a thinner thickness in step S210, and the second leading-out hole 103 is also formed in the first insulating layer 100, the second leading-out hole 103 may also have a smaller aspect ratio, thus a scope of a conductive material for filling the second leading-out hole 103 is expanded, and directly filling the second leading-out hole 103 with the aluminum becomes possible, which in turn omits the tungsten filling process, thereby reducing the complexity and cost of the lead process. In the implementations of the present application, the conductive material for filling the second leading-out hole 103 may be, but not limited to, tungsten, a metal and/or a metal alloy less than 10 g/cm3 in density.

It should be noted that, as can be seen from step S210 above, in the event that the intermediate semiconductor device 800 comprises the word line connection portion 700, the isolation hole 202 penetrating through the semiconductor layer 200 in the stacking direction is also required to be formed in a portion of the semiconductor layer 200 corresponding to the word line connection portion 700 before depositing the first insulating layer 100 on the first surface 201 of the semiconductor layer 200 (see FIG. 18). Thus, the first insulating layer 100 formed by step S210 may comprise a horizontal portion covering the first surface 201 and a convex portion 101 located within the isolation hole 202. Thus, the convex portion 101 is present between the second leading-out portion 520 formed in this step and the semiconductor layer 200, that is, the convex portion 101 is located between the second leading-out portion 520 and the semiconductor layer 200 in the x direction and the y direction, in other words, the first insulating layer 100 at least partially covers sidewalls of the second leading-out portion 520 in the stacking direction, i.e., the z direction, to isolate the second leading-out portion 520 from the semiconductor layer 200. Furthermore, it should also be noted that, the first leading-out portion 510 and the second leading-out portion 520 may be formed synchronously, in other words, the first leading-out hole 102 and the second leading-out hole 103 may be formed in the same process step, and further, the first leading-out hole 102 and the second leading-out hole 103 may be filled simultaneously during subsequent deposition of the conductive material.

As can be seen from the above, since the second leading-out hole 103 has a smaller aspect ratio, the second leading-out hole 103 may be filled directly with aluminum. Specifically, aluminum may be deposited on a side of the first insulating layer 100 far away from the semiconductor layer 200 using a thin film deposition process to cover the side of the first insulating layer 100 far away from the semiconductor layer 200 and fill the second leading-out hole 103; aluminum covering one side of the first insulating layer 100 is removed, wherein the aluminum within the second leading-out hole 103 constitutes the second leading-out portion 520. Similarly, since the aluminum is lower in density, the entire intermediate semiconductor device 800 will not be bent even if the thicker aluminum is deposited on one side of the first insulating layer 100 in order to completely fill the second leading-out hole 103. Certainly, the second leading-out hole 103 may also be filled with the tungsten in the present application. Similar to the above, a risk of bending the intermediate semiconductor device 800 exists when the second leading-out hole 103 is filled with the tungsten.

In some implementations, an aspect ratio of the second leading-out portion 520 is less than 1:4, which is a ratio of a depth of the second leading-out portion 520 in the stacking direction to a maximum width of a projection in the plane perpendicular to the stacking direction.

In addition, as shown in FIG. 21, the implementations of the present application further provides a semiconductor device, which comprises a stack structure 300, a semiconductor layer 200, a first insulating layer 100 and a first leading-out portion 510, wherein the stack structure 300 includes a core region 301 in which a plurality of channel structures 400 are formed, the semiconductor layer 200 is located on one side of the stack structure 300 in a stacking direction of the stack structure 300, the channel structures 400 extend to the semiconductor layer 200, and projections of the semiconductor layer 200 and the channel structures 400 in a plane parallel to the stacking direction do not overlap, the first insulating layer 100 is at least located on a first surface 201 of the semiconductor layer 200 far away from the stack structure 300, the first leading-out portion 510 penetrates through a portion of the first insulating layer 100 corresponding to the core region 301 in the stacking direction, and is in contact with the semiconductor layer 200.

Since the projections of the semiconductor layer 200 and the channel structures 400 of the semiconductor device in the plane parallel to the stacking direction do not overlap in the present application, in other words, the side of individual channel structures 400 facing towards the semiconductor layer 200 substantially keeps flush, and portions of the semiconductor layer 200 formed on the channel structures 400 are also substantially flush, the present application can not only enable the first insulating layer 100 to have a thinner thickness, further enable the first leading-out portion 510 to have a smaller aspect ratio, expand a material scope of the first leading-out portion 510, and make the formation of the first leading-out portion 510 directly using aluminum possible, thereby omitting a step of forming a first connection portion 530, reducing complexity of a lead process, but also can remove the restriction for a formation location of the first leading-out portion 510 due to different depths of individual channel structures 400 to enable the first leading-out portion 510 to be formed in any location of the first insulating layer corresponding to the core region 301, without being limited to locations corresponding to gate line slit structures 900, thereby reducing process difficulty of fabricating the first leading-out portion 510 and increasing an overlapping window.

In some implementations, a material of the first leading-out portion 510 includes a metal and/or a metal alloy less than 10 g/cm3 in density. As an example, a material of the first leading-out portion 510 is aluminum.

In some implementations, all the channel structures 400 have the same depth in the stacking direction, that is, all the channel structures 400 have the same depth in a z direction.

In some implementations, the thickness of a portion of the first insulating layer 100 in the core region 301 may be less than or equal to 1000 nm.

In some implementations, the semiconductor device further comprises a plurality of gate line slit structures 900 which penetrate through the stack structure 300 in the stacking direction and extend in a first direction, i.e., ay direction, perpendicular to the stacking direction, wherein the y direction is perpendicular to an x direction and the z direction, the z direction is the stacking direction, wherein a portion of the first surface 201 between two adjacent ones of the gate line slit structures 900 is a flat surface, the first leading-out portion 510 is located on the flat surface (see FIG. 21).

In some implementations, the first surface 201 of the semiconductor layer 200 is a flat surface (see FIG. 22). The flat surface may be implemented by removing part of initial channel structures 400′ and part of the gate line slit structures 900, the particular steps may be referred to the above, which is not repeated here.

In some implementations, the width of the first leading-out portion 510 in a second direction is 200 nm-1200 nm, the second direction is perpendicular to the first direction and the stacking direction. The first direction may be the y direction, the second direction may be the x direction, the stacking direction may be the z direction.

In some implementations, the semiconductor layer 200 may comprise a non-doped semiconductor layer 220, and a doped semiconductor layer 210 located on a side of the non-doped semiconductor layer 220 far away from the stack structure 300. As an example, each of the channel structures 400 extends to the non-doped semiconductor layer 220. Materials of the non-doped semiconductor layer 220 and the doped semiconductor layer 210 may be the same or different, for example, both of them may be polysilicon layers, with only a difference in doping or not. Taking that both the non-doped semiconductor layer 220 and the doped semiconductor layer 210 are polysilicon layers and that the non-doped semiconductor layer 220 is in direct contact with the doped semiconductor layer 210 as an example, although both of them are polysilicon, a very thin oxidation film (not shown in the figures) is quickly formed on the surface of the non-doped semiconductor layer 220 after the non-doped semiconductor layer 220 is formed because the non-doped semiconductor layer 220 and the doped semiconductor layer 210 are formed by two processes respectively, and the polysilicon layers are very easily oxidized, thus the doped semiconductor layer 210 formed subsequently is located over the oxidation film, in other words, a detectable interface, i.e., the above oxidation film, is present between the non-doped semiconductor layer 220 and the doped semiconductor layer 210.

In some implementations, the stack structure 300 further comprises a periphery region 302 on at least one side of the core region 301, the stack structure 300 comprises gate layers 310 and second insulating layers 320 that are alternately stacked in the stacking direction within the core region 301, wherein the semiconductor device may further comprise a word line connection portion 700 and a second leading-out portion 520, wherein the word line connection portion 700 is located in the periphery region 302 and electrically connected with the gate layers 310, the second leading-out portion 520 penetrates through the first insulating layer 100 in the stacking direction and is electrically connected with the word line connection portion 700; the first insulating layer 100 at least covers sidewalls of the second leading-out portion 520 extending in the stacking direction.

Similarly, since the projections of the semiconductor layer 200 and the channel structures 400 of the semiconductor device in the plane parallel to the stacking direction do not overlap in the present application, in other words, the side of individual structures 400 facing towards the semiconductor layer 200 substantially keeps flush, and the portions of the semiconductor layer 200 formed on the channel structures 400 are also substantially flush, the present application may enable the first insulating layer 100 to have a thinner thickness, the thickness of a portion of the first insulating layer 100 in the core region 301 has little difference from the thickness of a portion of the first insulating layer 100 in the periphery region 302, which in turn enables the second leading-out portion 520 to have a smaller aspect ratio, expands a material scope of the second leading-out portion 520 and makes the formation of the second leading-out portion 520 directly using aluminum possible, thereby omitting a step of forming a second connection portion 540, reducing the complexity of the lead process.

In some implementations, a material of the second leading-out portion 520 includes a metal and/or a metal alloy less than 10 g/cm3 in density. As an example, a material of the second leading-out portion 520 is aluminum.

In some implementations, an aspect ratio of the second leading-out portion 520 is less than 1:4, which is a ratio of a depth of the second leading-out portion 520 in the stacking direction to a maximum width of the projection in the plane perpendicular to the stacking direction.

In some implementations, the second leading-out portion 520 may be formed integrally, that is, the second leading-out portion 520 may be directly electrically connected with an external device, in other words, the second leading-out portion 520 in the implementations of the present application may replace the second connection portion 540 and a fourth connection portion 560.

In addition, an implementation of the present disclosure further provides a memory system, which comprises a controller and the above semiconductor device, the controller is coupled to the semiconductor device and used for controlling the semiconductor device to store data. The semiconductor device comprises at least one of a three-dimensional NAND memory and a three-dimensional NOR memory.

It should be understood that various forms of flows as shown above may be used, and steps thereof may be reordered, added or deleted. As an example, as long as expected results of the technical solutions of the present application can be achieved, various steps set forth in the present disclosure may be performed in parallel, in sequence, or in a different order, and there is no limitation herein in this regard.

The above detailed description does not constitute a limitation on the protection scope of the present disclosure. Those skilled in the art should understand that various modifications, combinations, sub-combinations and substitutions can be made according to design requirements by equalizing other factors. Any modifications, equivalent substitutions and improvements and the like made within the spirit and principles of the present disclosure shall be included in the protection scope of the present disclosure.

1. A semiconductor device, comprising:
a stack structure including a core region in which a plurality of channel structures are formed;
a semiconductor layer located on one side of the stack structure in a stacking direction of the stack structure, the channel structures extending to the semiconductor layer, and projections of the semiconductor layer and the channel structures in a plane parallel to the stacking direction not overlapping;
a first insulating layer at least located on a first surface of the semiconductor layer far away from the stack structure; and
a first leading-out portion penetrating through a portion of the first insulating layer corresponding to the core region in the stacking direction and being in contact with the semiconductor layer.

2. The semiconductor device of claim 1, wherein a material of the first leading-out portion includes a metal and/or a metal alloy less than 10 g/cm3 in density.

3. The semiconductor device of claim 2, wherein the material of the first leading-out portion is aluminum.

4. The semiconductor device of claim 1, wherein depths of all the channel structures in the stacking direction are the same.

5. The semiconductor device of claim 1, wherein the first surface is a flat surface.

6. The semiconductor device of claim 1, wherein:
the semiconductor device further includes a plurality of gate line slit structures which penetrate through the stack structure in the stacking direction and extend in a first direction perpendicular to the stacking direction, and
a portion of the first surface between the two adjacent ones of the gate line slit structures is a flat surface, the first leading-out portion is located on the flat surface.

7. The semiconductor device of claim 6, wherein a width of the first leading-out portion in a second direction is 200 nm-1200 nm, the second direction is perpendicular to the first direction and the stacking direction.

8. The semiconductor device of claim 1, wherein the semiconductor layer further comprises:
a non-doped semiconductor layer; and
a doped semiconductor layer located on a side of the non-doped semiconductor layer far away from the stack structure, and wherein each of the channel structures extends to the non-doped semiconductor layer.

9. The semiconductor device according to claim 1, wherein:
the stack structure further includes:
a periphery region on at least one side of the core region, and
gate layers and second insulating layers that are alternately stacked in the stacking direction within the core region, and
the semiconductor device further includes:
a word line connection portion located in the periphery region and electrically connected with the gate layers, and
a second leading-out portion penetrating through the first insulating layer in the stacking direction and electrically connected with the word line connection portion, the first insulating layer at least partially covering sidewalls of the second leading-out portion extending in the stacking direction.

10. The semiconductor device of claim 9, wherein an aspect ratio of the second leading-out portion is less than 1:4, the aspect ratio is a ratio of a depth of the second leading-out portion in the stacking direction to a maximum width of a projection in a plane perpendicular to the stacking direction.

11. The semiconductor device of claim 9, wherein a material of the second leading-out portion includes a metal and/or a metal alloy less than 10 g/cm3 in density.

12. The semiconductor device of claim 9, wherein the second leading-out portion is formed integrally.

13. A fabrication method of a semiconductor device, comprising:
forming a first insulating layer on one side of an intermediate semiconductor device, wherein the intermediate semiconductor device includes a stack structure and a semiconductor layer on one side of the stack structure in a stacking direction of the stack structure, the stack structure includes a core region in which a plurality of channel structures are formed, the channel structures extend to the semiconductor layer, and projections of the semiconductor layer and the channel structures in a plane parallel to the stacking direction do not overlap, the first insulating layer is at least formed on a first surface of the semiconductor layer far away from the stack structure; and
forming a first leading-out portion that penetrates through the first insulating layer in the stacking direction and is in contact with the semiconductor layer in a portion of the first insulating layer corresponding to the core region.

14. The fabrication method of the semiconductor device of claim 13, wherein forming the first leading-out portion that penetrates through the first insulating layer in the stacking direction and is in contact with the semiconductor layer further comprises:
forming a first leading-out hole penetrating through the first insulating layer in the stacking direction to expose part of the first surface of the semiconductor layer; and
filling a conductive material in the first leading-out hole to form the first leading-out portion.

15. The fabrication method of the semiconductor device of claim 13, wherein the stack structure further includes a periphery region on at least one side of the core region, the stack structure includes gate layers and second insulating layers that are alternately stacked in the stacking direction within the core region, the intermediate semiconductor device further comprises a word line connection portion that is located in the periphery region and electrically connected with the gate layers,
wherein forming the first insulating layer on the one side of the intermediate semiconductor device further includes:
forming an isolation hole penetrating through the semiconductor layer in the stacking direction in a portion of the semiconductor layer corresponding to the word line connection portion; and
forming the first insulating layer covering the first surface and filling the isolation hole.

16. The fabrication method of the semiconductor device of claim 15, wherein the fabrication method further comprises:
forming a second leading-out hole penetrating through the first insulating layer in the stacking direction to expose the word line connection portion in a portion of the first insulating layer in the isolation hole; and
filling a conductive material within the second leading-out hole to form a second leading-out portion.

17. The fabrication method of the semiconductor device claim 13, wherein before forming the first insulating layer on the one side of the intermediate semiconductor device, the fabrication method further comprises:
forming the intermediate semiconductor device based on an initial semiconductor device,
wherein the initial semiconductor device includes a plurality of initial channel structures, the stack structure, as well as a substrate insulating layer and a substrate that are disposed in sequence in the stacking direction of the stack structure, the initial channel structures penetrate through the stack structure and the substrate insulating layer in sequence and extend into the substrate, the channel structures includes portions of the initial channel structures in the stack structure.

18. The fabrication method of the semiconductor device of claim 17, wherein forming the intermediate semiconductor device based on the initial semiconductor device further comprises:
removing the substrate to expose portions of the initial channel structures in the substrate;
removing the substrate insulating layer and the exposed portions of the initial channel structures; and
forming the semiconductor layer.

19. The fabrication method of the semiconductor device of claim 18, wherein the initial channel structures include sacrificial structures in the substrate and the substrate insulating layer, and channel structures in the stack structure,
wherein removing the substrate insulating layer and the exposed portions of the initial channel structures further comprises:
removing the substrate insulating layer and functional layers of the sacrificial structures to expose one side of the stack structure and channel layers of the sacrificial structures;
at least removing the channel layers and dielectric layers of the sacrificial structures to expose part of the channel structures; and
filling isolation insulating layers within second gaps surrounded by dielectric layers of the channel structures to enclose the second gaps.

20. A memory system, including a controller and a semiconductor device, wherein:
the semiconductor device, includes:
a stack structure including a core region in which a plurality of channel structures are formed;
a semiconductor layer located on one side of the stack structure in a stacking direction of the stack structure, the channel structures extending to the semiconductor layer, and projections of the semiconductor layer and the channel structures in a plane parallel to the stacking direction not overlapping;
a first insulating layer at least located on a first surface of the semiconductor layer far away from the stack structure; and
a first leading-out portion penetrating through a portion of the first insulating layer corresponding to the core region in the stacking direction and being in contact with the semiconductor layer, and
the controller is coupled to the semiconductor device and used for controlling the semiconductor device to store data.
